(19) United States
(12) Patent Application Publication
(10) Pub. No.: US 2026/0191074 A1
(43) Pub. Date: Jul. 2, 2026

(54) HYBIRD BUMP STRUCTURES

(71) Applicant: Texas Instruments Incorporated, Dallas, TX (US)

(72) Inventors: Sylvester Ankamah-Kusi, McKinney, TX (US); Jeffrey Solas, Iloilo City (PH); Jie Chen, Plano, TX (US); Guangxu Li, Allen, TX (US); Harshpreet Singh Phull Bakshi, Dallas, TX (US); Blake Travis, Richardson, TX (US); Yutaka Suzuki, Allen, TX (US); Rajen Manicon Murugan, Dallas, TX (US)

(21) Appl. No.: 19/005,617

(22) Filed: Dec. 30, 2024

(51) Int. Cl. H01L 23/00

(52) U.S. Cl. CPC H10W 72/20; H10W 70/09; H10W 70/60; H10W 72/012; H10W 72/01235; H10W 72/221; H10W 72/222; H10W 72/223; H10W 72/227; H10W 72/234; H10W 72/237; H10W 72/248; H10W 72/252; H10W 72/255; H10W 90/00; H10W 90/726

(57) ABSTRACT

A semiconductor die comprises a first bump structure. The first bump structure comprises a pillar portion and a solder portion attached to the pillar portion. The first bump structure is a signal bump structure of the semiconductor die that transmits electrical signals between the semiconductor die and a leadframe. The semiconductor die further comprises a second bump structure. The second bump structure comprises a base portion, a plurality of pillar portions on the base portion, and a plurality of solder portions attached to the plurality of pillar portions. The second bump structure is a power bump structure of the semiconductor die that transmits power between the semiconductor die and the leadframe.

### FIELD

The present disclosure relates generally to bump structures between a semiconductor die and a leadframe, and more particularly to a hybrid bump structure to reduce current density.

### BACKGROUND

In some semiconductor packages, such as a qual flat no lead (QFN) HotRod power package, a semiconductor die is directly mounted to a leadframe via a plurality of bump structures. The HotRod power package is a thermally enhanced plastic package that uses a copper leadframe technology without any bond wires implemented by flipchip attaching a semiconductor die having a plurality of bump structures directly onto leads of a leadframe. The plurality of bump structures electrically connects the semiconductor die to the leadframe. The plurality of bump structures includes both signal bump structures and power bump structures. The signal bump structures may generally focus on transmitting electrical signals between the semiconductor die and the leadframe. The power bump structures may generally focus on transmitting power between the semiconductor die and the leadframe. The power bump structures may generally handle higher current density compared with the signal bump structures.

### SUMMARY

This summary is provided to introduce a selection of disclosed concepts in a simplified form that are further described below in the detailed description including the drawings provided. This summary is not intended to limit the scope of the claimed subject matter.

Disclosed aspects include a semiconductor die. The semiconductor die comprises a first bump structure. The first bump structure comprises a pillar portion and a solder portion attached to the pillar portion. The semiconductor die further comprises a second bump structure. The second bump structure comprises a base portion, a plurality of pillar portions on the base portion, and a plurality of solder portions attached to the plurality of pillar portions.

Disclosed aspects include a bump structure. The bump structure comprises a base portion. The bump structure also comprises a plurality of pillar portions on the base portion. The bump structure further comprises a plurality of solder portions attached to the plurality of pillar portions.

Disclosed aspects include a semiconductor package. The semiconductor package comprises a semiconductor die. The semiconductor die comprises a first bump structure. The first bump structure comprises a pillar portion and a solder portion attached to the pillar portion. The first bump structure is coupled to a signal pin of the semiconductor die. The semiconductor die further comprises a second bump structure. The second bump structure comprises a base portion, a plurality of pillar portions on the base portion, and a plurality of solder portions attached to the plurality of pillar portions. The second bump structure is coupled to a power pin of the semiconductor die. The semiconductor package also comprises a leadframe coupled to the semiconductor die. The semiconductor package further comprises a mold compound covering the semiconductor die and the leadframe.

Disclosed aspects include a method of forming a bump structure on a semiconductor die. The method comprises providing the semiconductor die including a redistribution layer. The method also comprises forming a seed layer on the redistribution layer. The method also comprises forming a base portion of the bump structure on the seed layer. The method also comprises forming a plurality of pillar portions on the base portion. The method further comprises attaching a plurality of solder portions to the plurality of pillar portions.

### BRIEF DESCRIPTION OF THE DRAWINGS

Reference will now be made to the accompanying drawings, which are not necessarily drawn to scale, wherein:

FIG. 1A is a 3D view of an example hybrid bump structure in accordance with certain aspects of present disclosure;

FIG. 1B is a top perspective view of the example hybrid bump structure of FIG. 1A;

FIG. 1C is a bottom perspective view of the example hybrid bump structure of FIG. 1A;

FIG. 1D is a cross-section view of the example hybrid bump structure of FIG. 1A;

FIG. 2A is a 3D view of an example semiconductor die having hybrid bump structures in accordance with certain aspects of present disclosure;

FIG. 2B is a top perspective view of the example semiconductor die of FIG. 2A;

FIG. 2C is a bottom perspective view of the example semiconductor die of FIG. 2A;

FIG. 2D is a cross-section view across line A-A of the example semiconductor die of FIG. 2A;

FIG. 2E is a cross-section view across line B-B of the example semiconductor die of FIG. 2A;

FIG. 3 illustrates a fabrication process for a hybrid bump structure on a semiconductor die in accordance with certain aspects of present disclosure;

FIG. 4 is a 3D view of an example semiconductor package employing hybrid bump structures in accordance with certain aspects of present disclosure.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

The terms “coupled to” or “couples with” (and the like) as used herein without further qualification are intended to describe either an indirect or direct electrical connection. Thus, if a first device couples to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

In a HotRod power package, a plurality of bump structures between a semiconductor die and a leadframe may be formed by an electroplating process or a ball drop process. In case SnAgCu (SAC) solder is used in the HotRod power package, the plurality of bump structures would be formed through the ball drop process. The ball drop process requires the plurality of bump structures having a circular cross-section for ball attachment. This would result in a limited area for the plurality of bump structures, and hence increasing current density in the plurality of bump structures, especially for the bump structures that transmit power between the semiconductor die and the leadframe.

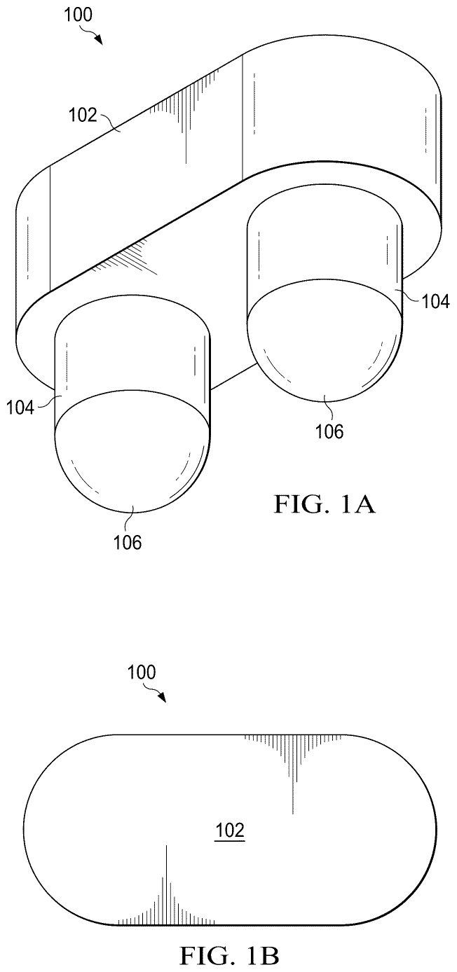

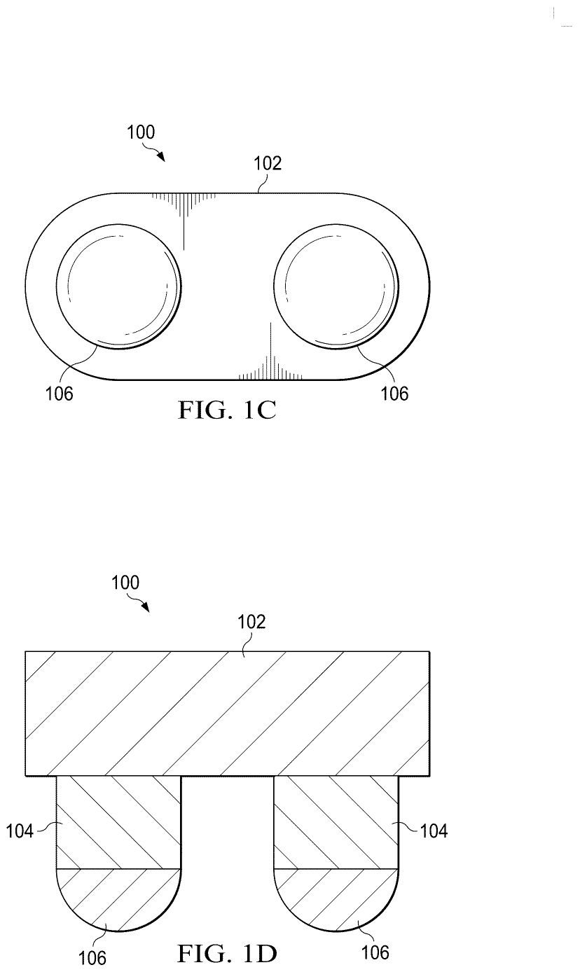

Disclosed aspects include a hybrid bump structure which could satisfy the requirements for the ball drop process as well as reduce current density in the bump structure. FIG. 1A is a 3D view of a hybrid bump structure 100 in accordance with certain aspects of present disclosure. FIG. 1B is a top perspective view of the hybrid bump structure 100 of FIG. 1A. FIG. 1C is a bottom perspective view of the hybrid bump structure 100 of FIG. 1A. And FIG. 1D is a cross-section view of the hybrid bump structure 100 of FIG. 1A. The hybrid bump structure 100 comprises a base portion 102, a plurality of pillar portions 104 on the base portion 102, and a plurality of solder portions 106 attached to the plurality of pillar portions 104. The base portion 102 and the plurality of pillar portions 104 may comprise copper (Cu) or other suitable conductive materials. The plurality of solder portions 106 may comprise SAC solder or other suitable solder materials. The base portion 102 is in direct contact with at least a first pillar portion and a second pillar portion of the plurality of pillar portions 104 and is formed by same material as the plurality of pillar portions 104. The base portion 102 may comprise an elongated shape with two curved edges or any other suitable shapes. The plurality of pillar portions 104 may comprise at least two pillar portions and each pillar portion may comprise a cylindrical shape with a circular cross-section, which is suitable for ball drop process. The plurality of solder portions 106 may be attached to the plurality of pillar portions 104 through a ball drop process. The base portion 102 could increase area for the hybrid bump structure 100, resulting in reduced current density. Thus, the hybrid bump structure 100 may satisfy the requirements for the ball drop process while reduce current density at the same time and is suitable for HotRod power package applications.

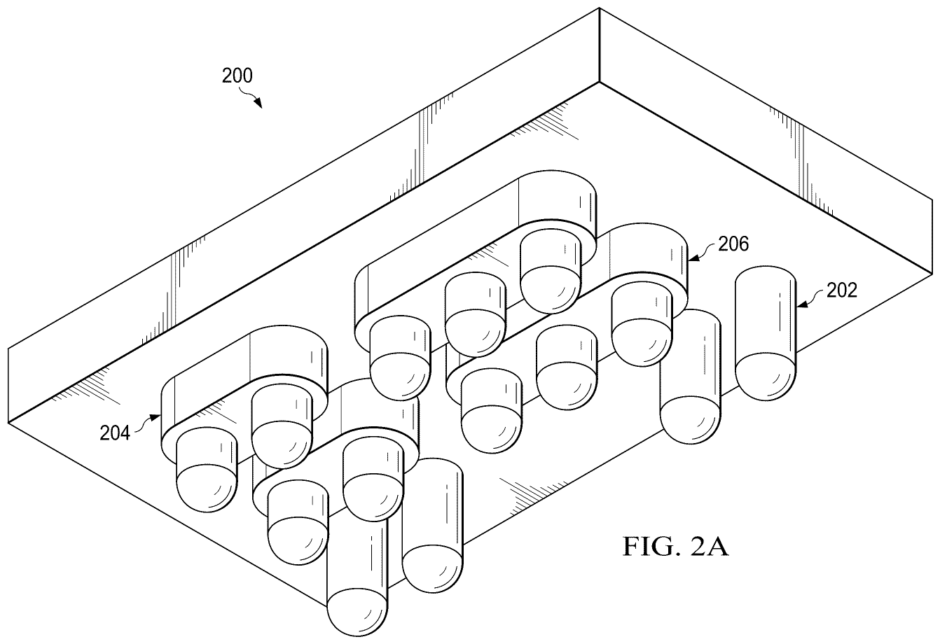

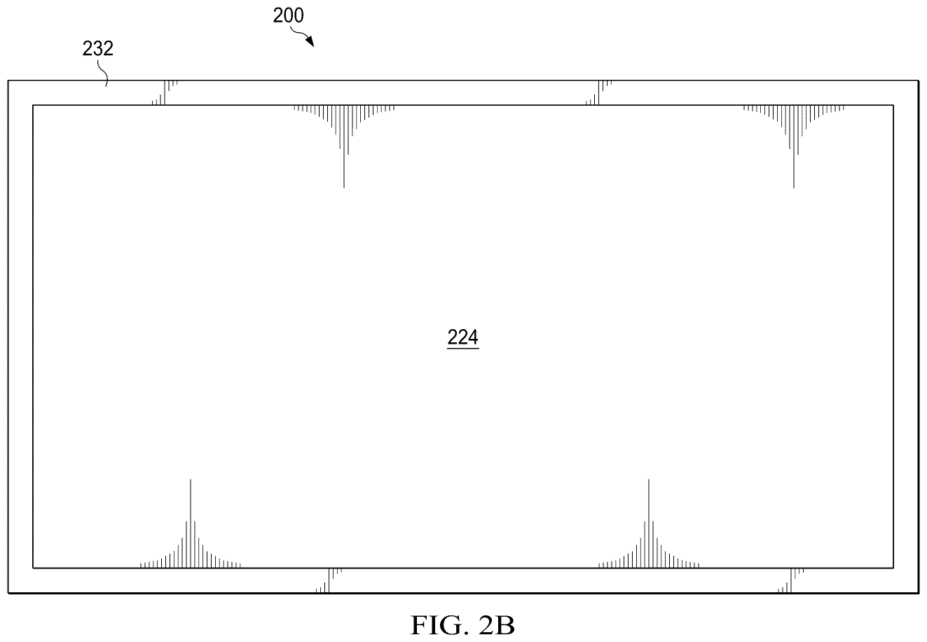

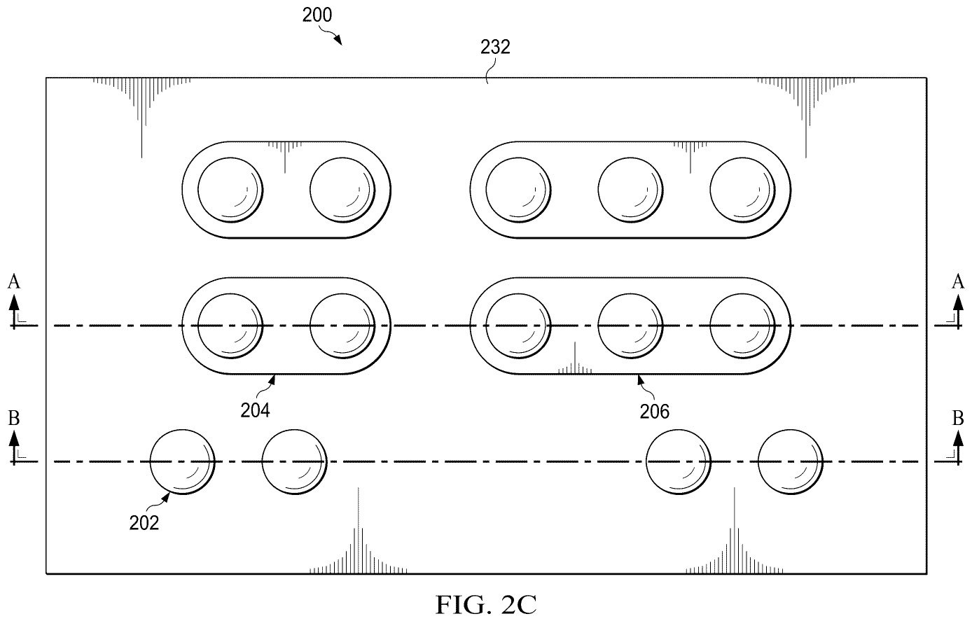

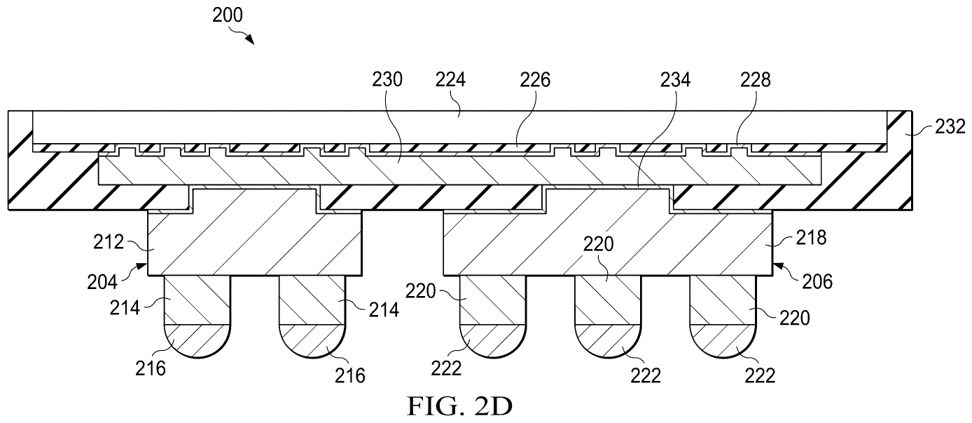

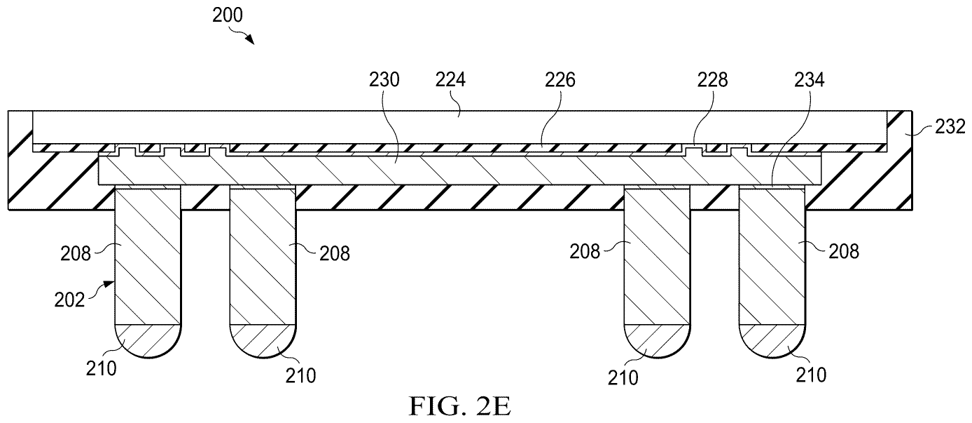

FIG. 2A is a 3D view of a semiconductor die 200 having hybrid bump structures in accordance with certain aspects of present disclosure. FIG. 2B is a top perspective view of the semiconductor die 200 of FIG. 2A. FIG. 2C is a bottom perspective view of the semiconductor die 200 of FIG. 2A. FIG. 2D is a cross-section view across line A-A of the semiconductor die 200 of FIG. 2A. And FIG. 2E is a cross-section view across line B-B of the semiconductor die 200 of FIG. 2A. The semiconductor die 200 comprises a first bump structure 202, a second bump structure 204, and a third bump structure 206. The first bump structure 202 comprises a pillar portion 208 and a solder portion 210 attached to the pillar portion 208. The pillar portion 208 may comprise Cu or other suitable conductive materials. The solder portion 210 may comprise SAC solder or other suitable solder materials. The pillar portion 208 may comprise a cylindrical shape with a circular cross-section, which is suitable for ball drop process. The solder portion 210 may be attached to the pillar portion 208 through a ball drop process. A diameter of the circular cross-section of the pillar portion 208 may be around 75 μm or 100 μm. A thickness of the pillar portion 208 may be around 50 μm. The first bump structure 202 may be a signal bump structure of the semiconductor die 200 that transmit electrical signals between the semiconductor die 200 and a leadframe or other suitable substrates. The first bump structure 202 may be coupled to a signal pin of the semiconductor die 200. The semiconductor die 200 also comprises a silicon portion 224, a passivation layer 226 on the silicon portion 224, and a redistribution layer (RDL) 230 on the silicon portion 224. The passivation layer 226 may comprise silicon nitride or silicon oxynitride. The RDL 230 may comprise Cu. The semiconductor die 200 also comprises a first seed layer 228 between the silicon portion 224 and the RDL 230. The first seed layer 228 may comprise titanium tungsten (TiW). The semiconductor die 200 also comprises a polyimide (PI) layer 232 on the RDL 230. The first bump structure 202 is on the RDL 230 and in contact with the PI layer 232. The semiconductor die 200 further comprises a second seed layer 234 between the first bump structure 202 and the RDL 230. The second seed layer 234 may comprise TiW.

The second bump structure 204 comprises a first base portion 212, a first plurality of pillar portions 214 on the first base portion 212, and a first plurality of solder portions 216 attached to the first plurality of pillar portions 214. The first base portion 212 and the first plurality of pillar portions 214 may comprise Cu or other suitable conductive materials. The first plurality of solder portions 216 may comprise SAC solder or other suitable solder materials. The first base portion 212 is in direct contact with at least a first pillar portion and a second pillar portion of the first plurality of pillar portions 214 and is formed by same material as the first plurality of pillar portions 214. The first base portion 212 may comprise an elongated shape with two curved edges or any other suitable shapes. The first plurality of pillar portions 214 may comprise at least two pillar portions and each pillar portion may comprise a cylindrical shape with a circular cross-section, which is suitable for ball drop process. The first plurality of solder portions 216 may be attached to the first plurality of pillar portions 214 through a ball drop process. The first base portion 212 could increase area for the second bump structure 204, resulting in reduced current density. The second bump structure 204 may be a power bump structure of the semiconductor die 200 that transmits power between the semiconductor die 200 and a leadframe or other suitable substrates. The second bump structure 204 may be coupled to a power pin of the semiconductor die 200. A diameter of the circular cross-section of each pillar portion of the first plurality of pillar portions 214 may be around 75 μm or 100 μm. A minimum distance between two adjacent pillar portions of the first plurality of pillar portions 214 may be around 60 μm. A thickness of the first base portion 212 plus the first plurality of pillar portions 214 may be around 50 μm. A thickness of the first base portion 212 may be between 25 μm and 40 μm. The thickness of the first base portion 212 may be larger than 25 μm to have sufficient area to reduce current density. The thickness of the first base portion 212 may be smaller than 40 μm to leave sufficient space between adjacent pillar portions of the first plurality of pillar portions 214 for mold compound filling. The second bump structure 204 is on the RDL 230 and in contact with the PI layer 232. The second seed layer 234 lies between the second bump structure 204 and the RDL 230.

The third bump structure 206 comprises a second base portion 218, a second plurality of pillar portions 220 on the second base portion 218, and a second plurality of solder portions 222 attached to the second plurality of pillar portions 220. The second base portion 218 and the second plurality of pillar portions 220 may comprise Cu or other suitable conductive materials. The second plurality of solder portions 222 may comprise SAC solder or other suitable solder materials. The second base portion 218 is in direct contact with at least a first pillar portion and a second pillar portion of the second plurality of pillar portions 220 and is formed by same material as the second plurality of pillar portions 220. The second base portion 218 may comprise an elongated shape with two curved edges or any other suitable shapes. The second plurality of pillar portions 220 may comprise at least two pillar portions and each pillar portion may comprise a cylindrical shape with a circular cross-section, which is suitable for ball drop process. The second plurality of solder portions 222 may be attached to the second plurality of pillar portions 220 through a ball drop process. The second base portion 218 could increase area for the third bump structure 206, resulting in reduced current density. The third bump structure 206 may be a power bump structure of the semiconductor die 200 that transmits power between the semiconductor die 200 and a leadframe or other suitable substrates. The third bump structure 206 may be coupled to a power pin of the semiconductor die 200. A diameter of the circular cross-section of each pillar portion of the second plurality of pillar portions 220 may be around 75 μm or 100 μm. A minimum distance between two adjacent pillar portions of the second plurality of pillar portions 220 may be around 60 μm. A thickness of the second base portion 218 plus the second plurality of pillar portions 220 may be around 50 μm. A thickness of the second base portion 218 may be between 25 μm and 40 μm. The thickness of the second base portion 218 may be larger than 25 μm to have sufficient area to reduce current density. The thickness of the second base portion 218 may be smaller than 40 μm to leave sufficient space between adjacent pillar portions of the second plurality of pillar portions 220 for mold compound filling. The third bump structure 206 is on the RDL 230 and in contact with the PI layer 232. The second seed layer 234 lies between the third bump structure 206 and the RDL 230.

The first plurality of pillar portions 214 may comprise a first number of pillar portions. The second plurality of pillar portions 220 may comprise a second number of pillar portions. The first number may be different from the second number. For example, the first number may be two and the second number may be three. Both the second bump structure 204 and the third bump structure 206 comprise a hybrid bump structure that satisfies the requirements for the ball drop process while reduces current density at the same time and are suitable for HotRod power package applications.

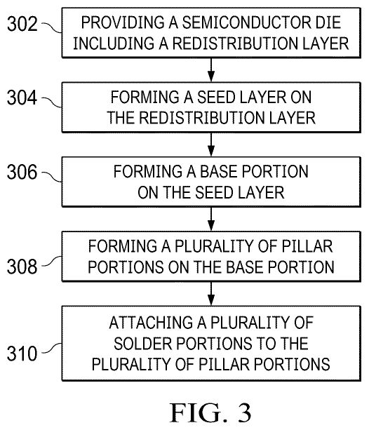

FIG. 3 illustrates a fabrication process for a hybrid bump structure on a semiconductor die in accordance with certain aspects of present disclosure. Step 302 comprises providing a semiconductor die including a redistribution layer. The redistribution layer may comprise Cu and may be formed by an electroplating process. Step 304 comprises forming a seed layer on the redistribution layer. The seed layer may comprise TiW and may be formed by a sputtering process. Step 306 comprises forming a base portion of the hybrid bump structure on the seed layer. The base portion may comprise Cu and may be formed by an electroplating process. The base portion may comprise an elongated shape with two curved edges. The base portion could increase area for the hybrid bump structure, resulting in reduced current density. Step 308 comprises forming a plurality of pillar portions on the base portion. The plurality of pillar portions may comprise Cu and may be formed by an electroplating process. The plurality of pillar portions may comprise at least two pillar portions and each pillar portion may comprise a cylindrical shape with a circular cross-section, which is suitable for ball drop process. Step 310 comprises attaching a plurality of solder portions to the plurality of pillar portions to form the hybrid bump structure. The plurality of solder portions may comprise SAC solder and may be attached to the plurality of pillar portions by a ball drop process. The hybrid bump structure may satisfy the requirements for the ball drop process while reduce current density at the same time and is suitable for HotRod power package applications.

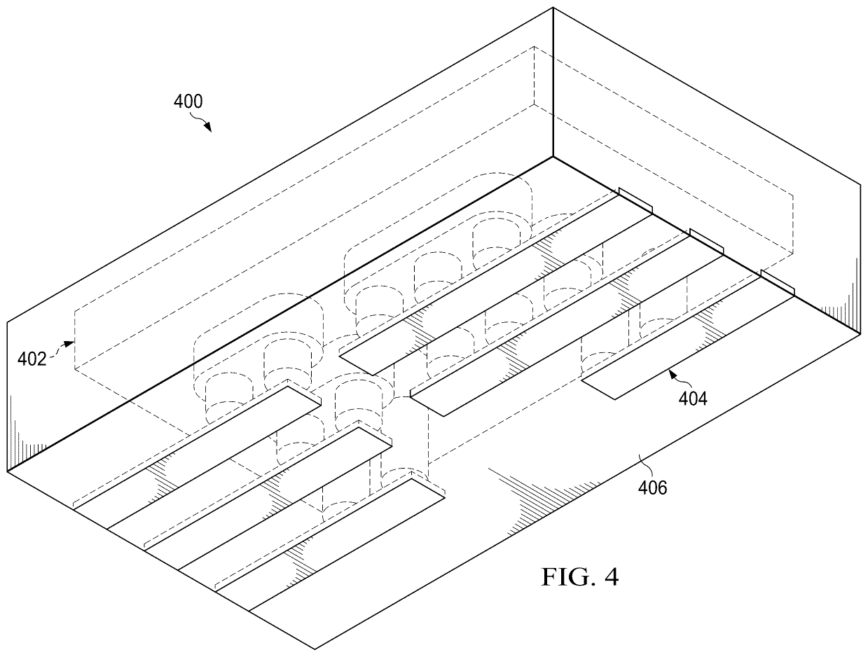

FIG. 4 is a 3D view of a semiconductor package 400 employing hybrid bump structures in accordance with certain aspects of present disclosure. The semiconductor package 400 comprises a semiconductor die 402. The semiconductor die 402 is similar to the semiconductor die 200. The semiconductor die 402 comprises a plurality of bump structures including hybrid bump structures. The semiconductor package 400 also comprises a leadframe 404. The semiconductor die 402 is coupled to the leadframe 404 through the plurality of bump structures. The semiconductor package 400 further comprises a mold compound 406 covering the semiconductor die 402 and the leadframe 404. The hybrid bump structures of the semiconductor die 402 could satisfy the requirements for the ball drop process while reduce current density at the same time and are suitable for HotRod power package applications. The semiconductor package 400 may be a HotRod power package.

In example embodiments, the terms “approximately,” “about,” and “around” mean that a value or range of values is either a stated value or range of values or within plus or minus 10% from that stated value or range of values.

Those skilled in the art to which this disclosure relates will appreciate that many variations of disclosed aspects are possible within the scope of the claimed invention, and further additions, deletions, substitutions, and modifications may be made to the above-described aspects without departing from the scope of this disclosure.

What is claimed is:

1. A semiconductor die, comprising:
a first bump structure, comprising a pillar portion and a solder portion attached to the pillar portion; and
a second bump structure, comprising a base portion, a plurality of pillar portions on the base portion, and a plurality of solder portions attached to the plurality of pillar portions.

2. The semiconductor die of claim 1, wherein the plurality of pillar portions comprises at least two pillar portions.

3. The semiconductor die of claim 2, wherein the base portion is in direct contact with at least a first pillar portion and a second pillar portion of the plurality of pillar portions.

4. The semiconductor die of claim 1, further comprising a redistribution layer, wherein the first bump structure and the second bump structure are on the redistribution layer.

5. The semiconductor die of claim 4, further comprising a seed layer between the redistribution layer and the first and second bump structures.

6. The semiconductor die of claim 1, wherein each pillar portion of the plurality of pillar portions has a first thickness.

7. The semiconductor die of claim 6, wherein a second thickness of the base portion is greater than the first thickness.

8. The semiconductor die of claim 7, wherein the pillar portion of the first bump structure has a third thickness greater than the first thickness and the second thickness.

9. The semiconductor die of claim 1, wherein the pillar portion of the first bump structure and the base portion and the plurality of pillar portions of the second bump structure comprise copper.

10. The semiconductor die of claim 1, wherein the solder portion of the first bump structure and the plurality of solder portions of the second bump structure comprise SnAgCu (SAC) solder.

11. The semiconductor die of claim 1, further comprising a third bump structure comprising a base portion, a plurality of pillar portions on the base portion, and a plurality of solder portions attached to the plurality of pillar portions.

12. The semiconductor die of claim 11, wherein the plurality of pillar portions of the second bump structure comprises a first number of pillar portions and the plurality of pillar portions of the third bump structure comprises a second number of pillar portions, and wherein the first number is different from the second number.

13. A bump structure, comprising:
a base portion;
a plurality of pillar portions on the base portion; and
a plurality of solder portions attached to the plurality of pillar portions.

14. The bump structure of claim 13, wherein the plurality of pillar portions comprises at least two pillar portions.

15. The bump structure of claim 14, wherein the base portion is in direct contact with at least a first pillar portion and a second pillar portion of the plurality of pillar portions.

16. The bump structure of claim 13, wherein each pillar portion of the plurality of pillar portions has a first thickness.

17. The bump structure of claim 16, wherein a second thickness of the base portion is greater than the first thickness.

18. The bump structure of claim 13, wherein the base portion and the plurality of pillar portions comprise copper.

19. A semiconductor package, comprising:
a semiconductor die, comprising a first bump structure, wherein the first bump structure comprises a pillar portion and a solder portion attached to the pillar portion, and wherein the first bump structure is coupled to a signal pin of the semiconductor die, and a second bump structure, wherein the second bump structure comprises a base portion, a plurality of pillar portions on the base portion, and a plurality of solder portions attached to the plurality of pillar portions, and wherein the second bump structure is coupled to a power pin of the semiconductor die;
a leadframe coupled to the semiconductor die; and
a mold compound covering the semiconductor die and the leadframe.

20. A method of forming a bump structure on a semiconductor die, comprising:
providing the semiconductor die including a redistribution layer;
forming a seed layer on the redistribution layer;
forming a base portion of the bump structure on the seed layer;
forming a plurality of pillar portions on the base portion; and
attaching a plurality of solder portions to the plurality of pillar portions.
